(19) United States
(12) Patent Application Publication
(10) Pub. No.: US 2008/0247437 A1
(43) Pub. Date: Oct. 9, 2008

(54) TUNABLE LONG-WAVELENGTH VCSEL SYSTEM

(76) Inventor: Bernhard Ulrich Koelle, Milpitas, CA (US)

Correspondence Address: Kathy Manke;Avago Technologies Limited, 4380 Ziegler Road, Fort Collins, CO, 80525, US

(21) Appl. No.: 12/143,646

(22) Filed: Jun. 20, 2008

Related U.S. Application Data
(62) Division of application No. 11/207,481, filed on Aug. 19, 2005.

(51) Int. Cl. H01S 5/00

(52) U.S. Cl. 372/50.11

(57) ABSTRACT

A vertical cavity surface emitting laser system is provided including providing a epitaxially grown bottom spacer layer, an active layer on the epitaxially grown bottom spacer layer, a top spacer layer on the active layer, and etching a part of the epitaxially grown top spacer layer on a side opposite the active layer.

### BACKGROUND

In the connected world, people create, transport, store, and consume vast amount of data from making a phone call, using the facsimile machine, and using the internet to name a few. We treat the technology that keeps people connected as ubiquitous and always available. Some of these technologies to transport the vast amount of data involve optics or lasers. One type of laser is called vertical cavity surface emitting laser (VCSEL) and is one of the technological components needed for the connected world. Market requirements demand that VCSEL manufacturability improves and price decreases.

VCSELs represent a relatively new class of semiconductor lasers. While there are many variations of VCSELs, one common characteristic is that they emit light perpendicular to a wafer's surface. In comparison to edge emitting lasers, this common VCSEL characteristic enables improved testing, improved manufacturing yield, and lowered cost. VCSELs can be formed from a wide range of material systems, e.g. material combinations and structures, to produce specific characteristics. In particular, the various material systems can be tailored to produce different laser wavelength.

As VCSELs enter new markets and proliferate in existing markets, the requirements for better performance, manufacturing yield, lower cost, as well as growing system requirements stimulate developments for new structures and material systems. In particular, long-wavelength (1000 nm to 2000 nm) VCSEL exists but continue to be a large area for research and product development.

### DISCLOSURE OF THE INVENTION

The present invention provides a vertical cavity surface emitting laser system including providing an epitaxially grown bottom spacer layer, providing an active layer on the epitaxially grown bottom spacer layer, providing a top spacer layer on the active layer, and etching a part of the epitaxially grown top spacer layer on a side opposite the active layer.

Certain embodiments of the invention have other configurations in addition to or in place of those mentioned above. The configurations will become apparent to those skilled in the art from a reading of the following detailed description when taken with reference to the accompanying drawings.

### BRIEF DESCRIPTION OF THE DRAWINGS

FIG. 1 is a cross-sectional view of a tunable long-wavelength VCSEL system, in an embodiment of the present invention;

FIG. 2 is a cross-sectional view of the tunable long-wavelength VCSEL system of FIG. 1 in a substrate attach phase;

FIG. 3 is a cross-sectional view of the tunable long-wavelength VCSEL system of FIG. 1 in a first tuning phase, after the substrate attach phase;

FIG. 4 is a cross-sectional view of the tunable long-wavelength VCSEL system of FIG. 1 in a second tuning phase, after first tuning phase;

FIG. 5 is a cross-sectional view of the tunable long-wavelength VCSEL system of FIG. 1 in a third tuning phase, after second tuning phase;

FIG. 6 is a cross-sectional view of the tunable long-wavelength VCSEL system of FIG. 1 in a tuning lift-off phase, after third tuning phase;

FIG. 7 is a cross-sectional view of the tunable long-wavelength VCSEL system of FIG. 1 in a mirror formation phase, after the tuning lift-off phase; and

FIG. 8 is a flow chart of a tunable long-wavelength VCSEL system for manufacturing the tunable long-wavelength VCSEL system in an embodiment of the present invention.

### BEST MODE FOR CARRYING OUT THE INVENTION

The following embodiments are described in sufficient detail to enable those skilled in the art to make and use the invention, and it is to be understood that other embodiments would be evident based on the present disclosure and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known structures, configurations, and process steps are not disclosed in detail.

Likewise, the drawings showing embodiments of the device are semi-diagrammatic and not to scale and, particularly, some of the dimensions are for the clarity of presentation and are shown greatly exaggerated in the drawing FIGs.

Similarly, although the sectional views in the drawings for ease of description show the exit ends of orifices as oriented upward, this arrangement in the FIGs. is arbitrary and is not intended to suggest that the delivery path should necessarily be in an upward direction. Generally, the device can be operated in any orientation. The same numbers are used in all the drawing FIGs. to relate to the same elements.

The term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane. The term “processing” as used herein includes deposition of material or photoresist, patterning, exposure, development, etching, cleaning, and/or removal of the material or photoresist as required in forming a described structure. The term “on” refers to direct contact between one element and another rather than referring to juxtaposition.

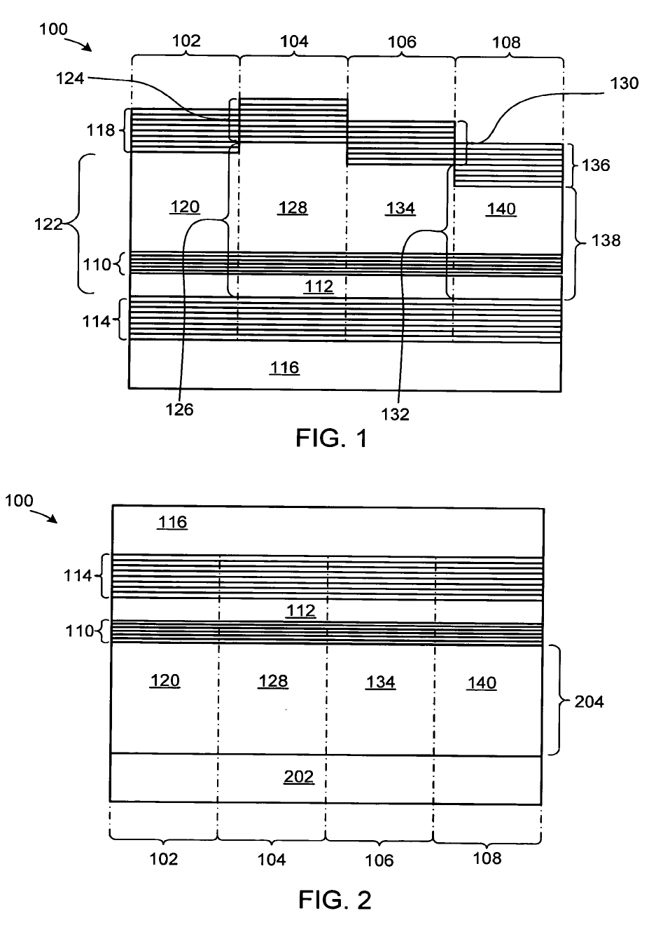

Referring now to FIG. 1, therein is shown a cross-sectional view of a tunable long-wavelength VCSEL system 100, in an embodiment of the present invention. The tunable long-wavelength VCSEL system 100 provides multiple wavelengths as a result of multiple optical cavities of different lengths. For clarity and brevity, other elements that may be commonly found in VCSEL structures are not represented, such as contacts for external bias connections, current confinement structures, and isolating regions.

The tunable long-wavelength VCSEL system 100 includes a first wavelength structure 102, a second wavelength structure 104, a third wavelength structure 106, and a fourth wavelength structure 108 with each emitting photons of different wavelengths. The first wavelength structure 102, the second wavelength structure 104, the third wavelength structure 106, and the fourth wavelength structure 108 include an active layer 110, a bottom spacer layer 112, and a bottom mirror 114. The bottom mirror 114 is above a substrate 116, such as a silicon substrate. The substrate 116 is representative of a single VCSEL substrate, a wafer, or a number of wafers. The active layer 110 is above the bottom spacer layer 112, wherein the bottom spacer layer 112 is above the bottom mirror 114.

The first wavelength structure 102 also includes a first top mirror 118 on a first top spacer layer 120, wherein the first top spacer layer 120 is above the active layer 110. A first optical cavity 122 is a region of the first wavelength structure 102 between the first top mirror 118 and the bottom mirror 114. The length of the first optical cavity 122 and the active layer 110 substantially determines a first wavelength emitted from the first wavelength structure 102. The first wavelength may be tuned to a desired value by varying the height of the first top spacer layer 120. The length of the first optical cavity 122 must be approximately a multiple of half of the first wavelength.

The first top spacer layer 120 is doped to a type complementary to the bottom spacer layer 112, such as the first top spacer layer 120 is n-type and the bottom spacer layer 112 is p-type. The electrons and holes from the first top spacer layer 120 and the bottom spacer layer 112, respectively, recombine in the active layer 110 resulting in photon emissions substantially of the first wavelength.

In a similar manner to the first wavelength structure 102, the second wavelength structure 104 includes a second top mirror 124 over a second optical cavity 126, wherein the second optical cavity 126 includes a second top spacer layer 128. The second wavelength structure 104 emits photons substantially of a second wavelength and may be tuned by varying the height of the second top spacer layer 128.

In a similar manner to the first wavelength structure 102, the third wavelength structure 106 includes a third top mirror 130 over a third optical cavity 132, wherein the third optical cavity 132 includes a third top spacer layer 134. The third wavelength structure 106 emits photons substantially of a third wavelength and may be tuned by varying the height of the third top spacer layer 134.

In a similar manner to the first wavelength structure 102, the fourth wavelength structure 108 includes a fourth top mirror 136 over a fourth optical cavity 138, wherein the fourth optical cavity 138 includes a fourth top spacer layer 140. The fourth wavelength structure 108 emits photons substantially of a fourth wavelength (not shown) and may be tuned by varying the height of the fourth top spacer layer 140.

The lengths of the first optical cavity 122, the second optical cavity 126, the third optical cavity 132, and the fourth optical cavity 138 are different resulting in a different wavelength generated by each optical cavity.

For illustrative purposes, the tunable long-wavelength VCSEL system 100 is shown with four wavelength structures providing four different wavelengths, although it is understood the number of wavelength structures and the number of wavelengths may differ, as well. It is also understood that the lengths of the first optical cavity 122, the second optical cavity 126, the third optical cavity 132, and the fourth optical cavity 138 may be in any relationship to each other.

Referring now to FIG. 2, therein is shown a cross-sectional view of the tunable long-wavelength VCSEL system 100 of FIG. 1 in a substrate attach phase. During this phase, the tunable long-wavelength VCSEL system 100 is formed on a formation substrate 202, such as an InP or InP-based material and is shown in an orientation vertically flipped from FIG. 1.

Some sacrificial etch stop layers (not shown) may be grown on the formation substrate 202 to facilitate ease of removal of the formation substrate 202 at a later stage in the process. An epitaxially grown top spacer layer 204, such as an InP or an InP-based material, is epitaxially grown on the sacrificial etch stop layers and above the formation substrate 202. The epitaxially grown top spacer layer 204 is shown prior to selective etching to form the four different regions. Selectively etching a first part of the epitaxially grown top spacer layer 204 forms the first top spacer layer 120. Similarly, selectively etching a second part of the epitaxially grown top spacer layer 204 forms the second top spacer layer 128. Similarly, selectively etching a third part of the epitaxially grown top spacer layer 204 forms the third top spacer layer 134. Similarly, selectively etching a fourth part of the epitaxially grown top spacer layer 204 forms the fourth top spacer layer 140.

It has been discovered that the present invention provides previously unachievable tight control over uniformity and thickness of the optical cavity lengths. The epitaxial growth allows tight control of the height of the epitaxially grown top spacer layer 204 such that the thickness variation is about or less than within 1% across a wafer 116.

Since etching uniformly etches the epitaxially grown top spacer layer 204, this means that all tunable long-wavelength VCSEL systems 100 from the same wafer specified to have the same wavelengths would have wavelengths about or less than within 1% of each other.

It has also been discovered that the present invention provides tight control of the height of the epitaxially grown top spacer layer 204 such that the thickness variation is within about 1% across all wafers 116.

This means that all tunable long-wavelength VCSEL systems 100 from all wafers 116 specified to have the same wavelengths would have wavelengths within 1% of each other.

The epitaxially grown top spacer layer 204 is doped forming an electrically conductive layer, such as n-type, providing an electrical connection for an external bias contact (not shown). The epitaxially grown top spacer layer 204 is grown to a predetermined height including the largest height of the first top spacer layer 120, the second top spacer layer 128, the third top spacer layer 134, and the fourth top spacer layer 140.

For illustrative purposes, the epitaxially grown top spacer layer 204 is shown as a single layer, although it is understood that the epitaxially grown top spacer layer 204 may include any number of stratified layers. It is also understood that any of the stratified layers of the epitaxially grown top spacer layer 204 may be doped differently, such as different doping concentration or different dopant type.

The active layer 110 is grown on the epitaxially grown top spacer layer 204, wherein the active layer 110 is typically intrinsic or very minimally doped. The active layer 110 includes one or more quantum wells (not shown). The quantum wells, which typically include a quantum well layer (not shown), sandwiched by a pair of barrier layers (not shown), are the layers into which carriers, such as electrons and holes, are injected. The electrons and holes recombine in the active layer 110 and emit photons at a wavelength determined by the material layers in the quantum well. The quantum well layer includes a low band gap semiconductor material, while the barrier layer has a band gap higher than the band gap of the quantum well layer. When the device is subject to forward bias, electrons and holes are injected into and trapped in the quantum well layer and recombined to emit coherent light at a particular wavelength.

For illustrative purposes, the active layer 110 may be an indium phosphide based, such as the material pair for the quantum well layer and the barrier layer of InGaAsP and InGaAsP, respectively, or of InAlGaAs and InP, respectively. The materials used for the quantum well layer and the barrier layer provide lattice matching between these layers as well as with the bottom spacer layer 112 and the epitaxially grown top spacer layer 204. Although it is also understood the active layer 110 may include other active material, such as quantum wires or quantum dots.

The bottom spacer layer 112 is grown on the active layer 110. The bottom spacer layer 112 is doped to a type complementary to the epitaxially grown top spacer layer 204. The bottom spacer layer 112 forms an electrically conductive layer, such as p-type, providing an electrical connection for an external bias contact (not shown). For illustrative purposes, the bottom spacer layer 112 is shown as a single layer, although it is understood that the bottom spacer layer 112 may include any number of stratified layers. It is also understood that any of the stratified layers of the bottom spacer layer 112 may be doped differently, such as different doping concentration or different dopant type. Also for illustrative purposes, the epitaxially grown top spacer layer 204 is described doped as n-type resulting in the bottom spacer layer 112 doped as p-type, although it is understood the doping type may differ, as well.

The bottom mirror 114, such as a dielectric mirror, is deposited on the bottom spacer layer 112. For illustrative purposes, the bottom mirror 114 is shown as a dielectric mirror, although it is understood that the bottom mirror 114 may be constructed of other materials, such as semiconductor materials that may be lattice matched to the material of the bottom spacer layer 112. The semiconductor materials may be grown on the bottom spacer layer 112.

The bottom mirror 114 is formed of multiple layer pairs of complementary refractive material. The multiple layer pairs create an alternating structure where each layer pair includes a high refractive layer (not shown) and a low refractive layer (not shown). Such a complementary layer pair can be made from a number of different combinations of materials including semiconductor layers, dielectric materials such as TiO₂ (titanium dioxide) for the high refractive layer and SiO₂ (silicon dioxide) for the low refractive layer, or hybrid combinations of semiconductor, dielectric and metal layers. Materials and construction determine the type of reflector such as a “dielectric” distributed Bragg reflector (DBR) or a semiconductor DBR or a metal DBR.

For illustrative purpose, the present invention discloses the bottom mirror 114 as a dielectric DBR, but it is understood that the present invention can be implemented with other types of DBR, such as a semiconductor or metal DBR. It is further understood that different compounds such as quaternary compounds of indium gallium aluminum arsenide (InGaAlAs), or indium gallium aluminum arsenide phosphide (InGaAlAsP), or aluminum gallium arsenide antimonide (AlGaAsSb), and aluminum gallium phosphide antimonide (AlGaPSb) may be used as the high refractive layer 702 in combination with the low refractive layer 704 such as binary indium phosphide layers, ternary indium/aluminun/arsenic (InAlAs), aluminum/arsenic/antimony (AlAsSb) or aluminum/phosphorous/antimony (AIPSb) layers.

Bonding metal layer (not shown), such as palladium (Pa) or tantalum (Ta) based material, is applied on the bottom mirror 114 or on the substrate 116 with a physical vapor deposition (PVD) or a similar process. The substrate 116 attaches to the bottom mirror 114 on a side opposite the bottom spacer layer 112. The substrate 116 may be used to provide a platform to form an array of the tunable long-wavelength VCSEL system 100.

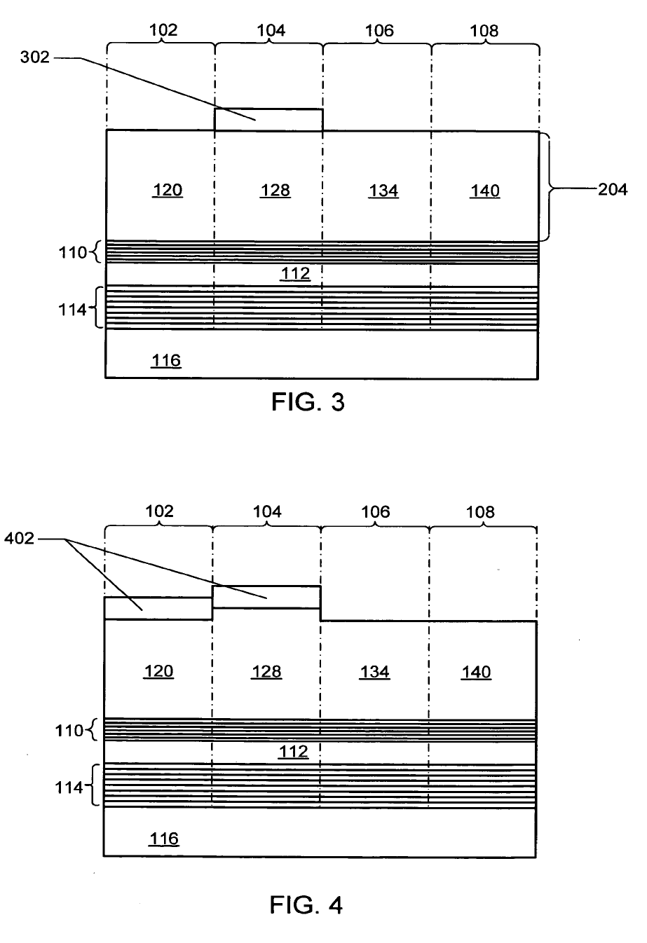

Referring now to FIG. 3, therein is shown a cross-sectional view of the tunable long-wavelength VCSEL system 100 of FIG. 1 in a first tuning phase, after the substrate attach phase. During this phase, the formation substrate 202 of FIG. 2 is removed with selective etching exposing the epitaxially grown top spacer layer 204. The first tuning phase is the initial etching phase creating the different optical cavity lengths by selectively removing thin layers of epitaxial growth of the epitaxially grown top spacer layer 204. A first tuning mask 302 protects the surface of the epitaxially grown top spacer layer 204 of the second wavelength structure 104 from the first tuning selective etching. For illustrative purposes, the first tuning mask 302 is shown to protect only the second top spacer layer 128, although it is understood that the first tuning mask 302 may protect the first top spacer layer 120, the third top spacer layer 134, the fourth top spacer layer 140, or a combination thereof.

Referring now to FIG. 4, therein is shown a cross-sectional view of the tunable long-wavelength VCSEL system 100 of FIG. 1 in a second tuning phase, after first tuning phase. The first top spacer layer 120, the third top spacer layer 134, and the fourth top spacer layer 140 have been selectively etched to a similar depth. The first tuning mask 302 of FIG. 3 is lifted off and a second tuning mask 402 protects the first top spacer layer 120 and the second top spacer layer 128 from the second tuning selective etching.

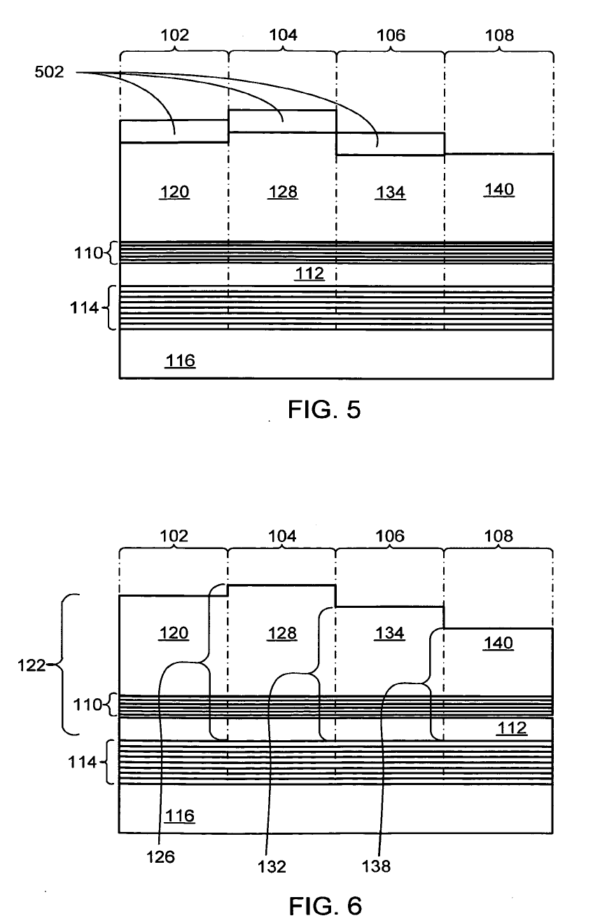

Referring now to FIG. 5, therein is shown a cross-sectional view of the tunable long-wavelength VCSEL system 100 of FIG. 1 in a third tuning phase, after second tuning phase. The third top spacer layer 134 and the fourth top spacer layer 140 have been further selectively etched to a similar depth. The second tuning mask 402 of FIG. 4 is lifted off and a third tuning mask 502 protects the first top spacer layer 120, the second top spacer layer 128, and the third top spacer layer 134 from the third tuning selective etching.

Referring now to FIG. 6, there is shown a cross-sectional view of the tunable long-wavelength VCSEL system 100 of FIG. 1 in a tuning lift-off phase, after third tuning phase. The fourth top spacer layer 140 has been further selectively etched. The third tuning mask 502 of FIG. 5 is lifted off. The first top spacer layer 120, the second top spacer layer 128, the third top spacer layer 134, and the fourth top spacer layer 140 have different heights to form different cavity lengths for the first optical cavity 122, the second optical cavity 126, the third optical cavity 132, and the fourth optical cavity 138, respectively. The different cavity lengths result in different wavelengths emitted from the first wavelength structure 102, the second wavelength structure 104, the third wavelength structure 106, and the fourth wavelength structure 108. The selective etching may remove thin epitaxially grown layers for small difference in the heights between the first top spacer layer 120, the second top spacer layer 128, the third top spacer layer 134, and the fourth top spacer layer 140. The selective etching in the first, second, and third tuning phases did not impact the active layer 110.

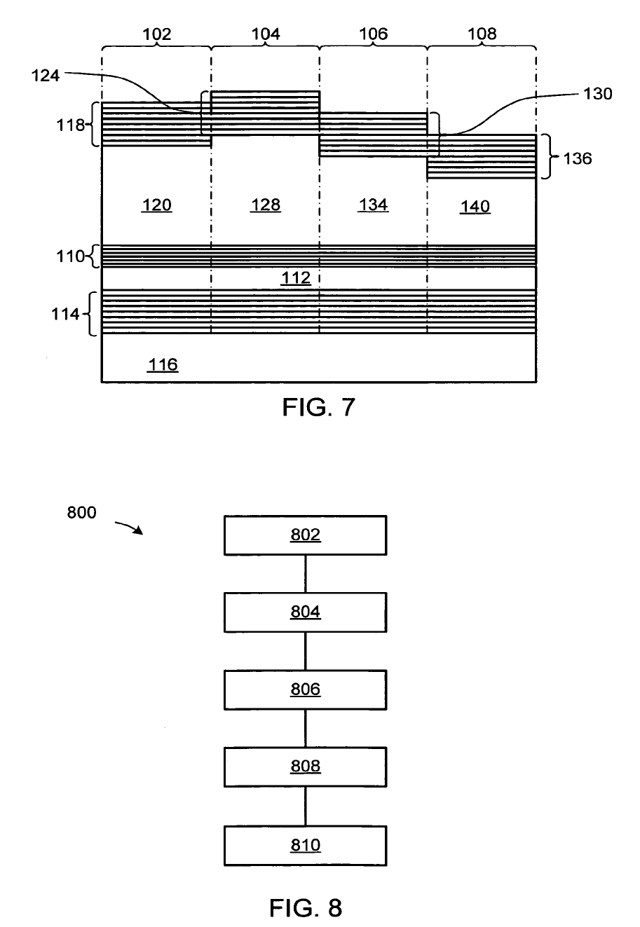

Referring now to FIG. 7, therein is shown a cross-sectional view of the tunable long-wavelength VCSEL system 100 of FIG. 1 in a mirror formation phase, after the tuning lift-off phase. During this phase, the first top mirror 118, the second top mirror 124, the third top mirror 130, and the fourth mirror 136 are formed on the first top spacer layer 120, the second top spacer layer 128, the third top spacer layer 134, and the fourth top spacer layer 140, respectively. The top mirrors may be formed in any number of processes.

For dielectric mirrors, dielectric materials may be deposited on the first top spacer layer 120, the second top spacer layer 128, the third top spacer layer 134, and the fourth top spacer layer 140 to a predetermined height. Dielectric curvatures resulting from the different heights of the first top spacer layer 120, the second top spacer layer 128, the third top spacer layer 134, and the fourth top spacer layer 140 are minimal.

Other materials, such as semiconductor materials that are lattice matched to the epitaxially grown top spacer layer 204 of FIG. 2, may be grown on the first top spacer layer 120, the second top spacer layer 128, the third top spacer layer 134, and the fourth top spacer layer 140 to the predetermined heights. Selectively etching may vary the heights as desired.

Referring now to FIG. 8, therein is shown a flow chart of a tunable long-wavelength VCSEL system 800 for manufacturing the tunable long-wavelength VCSEL system 100 in an embodiment of the present invention. The method 800 includes providing a top spacer layer in a block 802; forming an active layer on the top spacer layer in a block 804; growing a bottom spacer layer on the active layer in a block 806; placing a substrate over the epitaxially grown top spacer layer in a block 808; and etching a part of the top spacer layer on a side opposite the active layer in a block 810.

It has been discovered that the present invention thus has numerous aspects.

One aspect is that the present invention is tuning the cavity length, which may be tuned by selectively etching epitaxially grown multi-layers, to result in different Fabry-Perot resonator/cavity lengths for different wavelengths; this can be done within the wafer (to adjust wavelength uniformity within a wafer), or on a smaller scale as within a chip (e.g. for WDM applications). When increasing the VCSEL cavity length (e.g. to several wavelengths), the tuning etch depth(s) for a given set of resonance wavelengths also increases, which results in a more controllable and manufacturable tuning process.

For a long cavity device, asymmetric placement of the quantum wells (QWs on the opposite side of the etchable tuning layers of the cavity) is well suited for this application; this is because the optical standing wave pattern around the quantum wells changes little as the cavity length changes. That fact provides little laser threshold variation for a wide tuning range, while also providing reasonably thick layers to be etched for tuning, easing manufacturing concerns of controllably etching very thin layers. For high device density applications, this approach is limited by the spatial resolution of the selective tuning etch, allowing for a high laser device density within a chip.

These and other valuable aspects of the present invention consequently further the state of the technology to at least the next level.

Thus, it has been discovered that the tunable long-wavelength VCSEL system with multiple wavelengths generation method and apparatus of the present invention furnish important and heretofore unknown and unavailable solutions, capabilities, and functional aspects for VCSEL design, manufacturing, and operation. The resulting processes and configurations are straightforward, cost-effective, uncomplicated, highly versatile and effective, can be implemented by adapting known technologies, and are thus readily suited for efficiently and economically manufacturing VCSEL devices that are fully compatible with conventional manufacturing processes and technologies.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

1. A vertical cavity surface emitting laser system comprising:
providing an epitaxially grown bottom spacer layer,
an epitaxially grown active layer on the bottom spacer layer,
an epitaxially grown top spacer layer on the active layer; and
etching a part of the epitaxially grown top spacer layer on a side opposite the active layer.

2. The system as claimed in claim 1 wherein:
providing the epitaxially grown top spacer layer provides an epitaxially grown top spacer layer of a predetermined height; and
etching of the epitaxially grown top spacer layer is performed without impacting the active layer.

3. The system as claimed in claim 1 wherein etching the part of the epitaxially grown top spacer layer on a side opposite the active layer includes etching the epitaxially grown top spacer layer in different parts to different heights to cause a predetermined wavelength spacing.

4. The system as claimed in claim 1 further comprises:
forming additional vertical cavity surface emitting laser systems on a wafer that includes the substrate; and
forming the additional vertical cavity surface emitting laser systems specified to have the same wavelengths to have wavelengths within about 1% of each other on the wafer.

5. The system as claimed in claim 1 further comprises:
forming additional vertical cavity surface emitting laser systems on a plurality of wafers; and
forming the additional vertical cavity surface emitting laser systems specified to have the same wavelengths to have wavelengths about 1% of each other on the plurality of wafers.

6. A vertical cavity surface emitting laser system comprising:
providing a formation substrate;
growing an epitaxially grown top spacer layer on the formation substrate;
forming an active layer on the epitaxially grown top spacer layer;
growing a bottom spacer layer on the active layer;
placing a substrate over the bottom spacer layer;
removing the formation substrate;
forming a first top spacer layer by selectively etching a first part of the epitaxially grown top spacer layer on a side opposite the active layer;
forming a second top spacer layer by selectively etching a second part of the epitaxially grown top spacer layer on the side opposite the active layer; and
forming a third top spacer layer by selectively etching a third part of the epitaxially
grown top spacer layer on the side opposite the active layer.

7. The system as claimed in claim 6 further comprising forming a first longwavelength structure comprises forming a first top mirror on the first top spacer layer and forming a bottom mirror on the bottom spacer layer.

8. The system as claimed in claim 6 wherein etching the part of the epitaxially grown top spacer layer on a side opposite the active layer includes etching the epitaxially grown top spacer layer in different parts.

9. The system as claimed in claim 6 further comprises:
forming further long-wavelength vertical cavity surface emitting laser systems on a wafer that includes the substrate; and
forming the further vertical cavity surface emitting laser systems specified to have the same wavelengths to have wavelengths within 1% of each other on the wafer.

10. The system as claimed in claim 6 further comprises:
forming further long-wavelength vertical cavity surface emitting laser systems on a plurality of wafers that include the substrate; and
forming the further vertical cavity surface emitting laser systems specified to have the same wavelengths to have wavelengths within 1% of each other on the plurality of wafers.

11. A vertical cavity surface emitting laser system comprising:
a substrate;
a bottom mirror on top of the substrate;
a bottom spacer layer on top of the bottom mirror;
an active layer on top of the bottom spacer;
an epitaxially grown top spacer layer on top of the active layer;
wherein the epitaxially grown top spacer layer completely covers the active layer;
wherein the epitaxially grown top spacer layer has different parts with different heights, the different heights for providing different wavelengths having predetermined wavelength spacings.

12-20. (canceled)

21. The system as claimed in claim 11 further comprising a first wavelength structure including a first top mirror on the first top spacer layer.

22. The system as claimed in claim 11 wherein the first, second, and third predetermined heights are for causing the first, second, and third top spacer layers to cause a wavelength spacing.
